(19) United States
(12) Patent Application Publication
(10) Pub. No.: US 2010/0141275 A1
(43) Pub. Date: Jun. 10, 2010

(54) Electrostatic capacitance detection device, electrostatic capacitance detection circuit, electrostatic capacitance detection method, and initialization method

(76) Inventor: Kenichi Matsushima, Chiba-shi (JP)

Correspondence Address: BRUCE L. ADAMS, ESQ.;ADAMS & WILKS, SUITE 1231, 17 BATTERY PLACE, NEW YORK, NY, 10004, US

(21) Appl. No.: 12/592,430

(22) Filed: Nov. 24, 2009

(30) Foreign Application Priority Data
Nov. 26, 2008 (JP) 2008-300720

(51) Int. Cl. G01R 27/26

(52) U.S. Cl. 324/678

(57) ABSTRACT

Provided are an electrostatic capacitance detection circuit and an electrostatic capacitance detection method with which being capable of detecting minute change in electrostatic capacitance from which offset is removed for detection of approach of an object or the like, at high speed and high resolution while selecting an optimum detection range, with such a simpler configuration as to add a resistor and a capacitor to one input/output port of a general-purpose microcomputer. In the electrostatic capacitance detection circuit and the electrostatic capacitance detection method, a voltage waveform generated by the added capacitor is compared with a threshold voltage while controlling a DC component of the voltage waveform to change in correspondence with the change in electrostatic capacitance and an AC component of the voltage waveform to correspond to a width of a detection range.

### BACKGROUND OF THE INVENTION

1. Field of the Invention

The present invention relates to a method and circuit for detecting an electrostatic capacitance or change in electrostatic capacitance, which are used to detect approach of an object, coordinates of the approaching object, and the like.

2. Description of the Related Art

An electrostatic capacitance detection circuit detects approach of an external object, coordinates of the approaching object, and the like, to thereby obtain information mainly on a position of a fingertip and movement thereof. When an external object approaches, change occurs in electrostatic capacitance of a detection target. On this occasion, in order to determine the electrostatic capacitance of the detection target or change in electrostatic capacitance thereof, charge/discharge is performed on the electrostatic capacitance of the detection target, and a quantity of charges flowing at this time is converted into a digital value by means of a delta-sigma type AD converter or the like. This method enables approach of the object and coordinates of the approaching object to be detected, and is utilized for portable terminals and the like adopting a touch panel.

An example of a conventional electrostatic capacitance detection circuit which detects an electrostatic capacitance is described with reference to FIG. 2 (see “Capacitance Sensing—Migrating from CSR to CSD AN2408”, Cypress, Feb. 8, 2007, p. 2). One terminal of a detection target 1 is connected to a constant voltage source having, for convenience sake, an arbitrary value. Another terminal of the detection target 1 is connected to one terminal of a switch SWd and to one terminal of a switch SWc. Another terminal of the switch SWc is connected to a constant voltage source 3. Hereinafter, the switch SWc, the switch SWd, and the constant voltage source 3 are collectively referred to as CQ conversion means 14. Another terminal of the switch SWd is connected to one terminal of a resistor Rs 5 and to one terminal of an integration capacitor Ci 7, and outputs of the switch SWd and the integration capacitor Ci 7 are connected to comparison means 8. Another terminal of the resistor Rs 5 is connected to one terminal of a switch SWs, and another terminal of the switch SWs is connected to a constant voltage source 6. Another terminal of the integration capacitor Ci 7 is connected to a constant voltage source having an arbitrary value, such as a ground. An output of the comparison means 8 is input to sampling means 9. The sampling means 9 is realized by a latch circuit or the like. The above-mentioned switch SWs is controlled based on sampling results of the sampling means 9. An output of the sampling means 9 is input to arithmetic means 12, and then the arithmetic means 12 performs filtering on the output to be converted into a digital charge quantity. The above-mentioned resistor Rs 5, switch SWs, constant voltage source 6, integration capacitor Ci 7, comparison means 8, sampling means 9, and filter form together a delta-sigma type AD converter 15. The switch SWc and the switch SWd are controlled by charge/discharge control means 11 so as to be alternately turned on. Further, the arithmetic means 12 determines an electrostatic capacitance of the detection target 1 based on the digital charge quantity, which has been determined in the delta-sigma type AD converter, and an output of the charge/discharge control means 11.

In FIG. 2, a capacitor Cx represents the electrostatic capacitance of the detection target 1. The CQ conversion means 14 has a function of charging and discharging the electrostatic capacitance Cx of the detection target 1 to convert the electrostatic capacitance Cx into a charge quantity Qx corresponding to the electrostatic capacitance Cx. Here, the switch SWc is used to connect the constant voltage source 3 with the electrostatic capacitance Cx to thereby charge the electrostatic capacitance Cx, and the switch SWd is used to connect the electrostatic capacitance Cx with the delta-sigma type AD converter 15 to thereby discharge charged charges. Therefore, the switch SWc and the switch SWd are normally controlled by the charge/discharge control means 11 so as to be alternately turned on.

Note that the switch SWd need not always be a switch, and the switch SWd may be replaced with a resistor. In the case of using a resistor, while the switch SWc is turned on, a current irrelevant to the electrostatic capacitance Cx flows into the delta-sigma type AD converter 15 from the constant voltage source 3. There have been taken countermeasures to eliminate an influence of this current by making a period during which the switch SWc is turned on as short as possible or by subtracting a value corresponding to the current from a converted digital value as needed.

The charge quantity Qx from the CQ conversion means 14 is converted by the delta-sigma type AD converter 15 into a digital value. The delta-sigma type AD converter 15 includes integration means, which is the integration capacitor Ci 7, for performing integration on charges to be determined to thereby convert the charges into a voltage, the comparison means 8 for binarization, the sampling means 9, which is realized by a latch circuit or the like, 1-bit DA conversion means 10, which is formed of the resistor Rs 5 and the switch SWs, for providing negative feedback to an analogue input of the comparison means 8 based on sampling results of the sampling means 9, and the filter, which is a counter, a digital filter, or the like, for performing filtering on sampling results of the sampling means 9 to thereby convert the sampling results into a digital charge quantity. Note that because the negative feedback is provided in the delta-sigma type AD converter 15, an input voltage of the delta-sigma type AD converter 15 is controlled to be substantially equal to a threshold voltage Vt of the comparison means 8.

The arithmetic means 12 determines the electrostatic capacitance of the detection target 1 through arithmetic operations based on the number of charge/discharge times from the charge/discharge control means 11, a difference between a voltage Vc of the constant voltage source 3 and the threshold voltage Vt of the comparison means 8, and the digital charge quantity determined in the delta-sigma type AD converter 15. Note that the number of charge/discharge times from the charge/discharge control means 11 and the difference between the voltage Vc of the constant voltage source 3 and the threshold voltage Vt of the comparison means 8 are respectively predetermined values in many cases. Therefore, in many cases, the arithmetic means 12 determines a value corresponding to the electrostatic capacitance Cx of the detection target merely by performing filtering on sampling results of the sampling means.

As described above, in the conventional electrostatic capacitance detection circuit, the CQ conversion means for converting an electrostatic capacitance into a charge quantity and the delta-sigma type AD converter are separately incorporated, which arises a problem that the number of circuit elements is increased to lead to high component cost.

### SUMMARY OF THE INVENTION

It is therefore an object of the present invention to reduce the number of circuit elements by integrating CQ conversion means and a delta-sigma type AD converter, to thereby reduce component cost.

An electrostatic capacitance detection circuit according to the present invention includes: CQ supplement means having functions of converting an electrostatic capacitance Cx of a detection target into a charge quantity Qx corresponding to the electrostatic capacitance Cx of the detection target, and of supplementing with a charge quantity corresponding to the converted charge quantity Qx and performing integration; comparison means for comparing an output obtained from the CQ supplement means with a threshold voltage Vt; sampling means for sampling an output of the comparison means and providing negative feedback to the CQ supplement means; and arithmetic means for determining one of the electrostatic capacitance Cx of the detection target or change in electrostatic capacitance Cx based on sampling results of the sampling means.

Further, an electrostatic capacitance detection method according to the present invention is realized by including: a CQ supplement step of converting an electrostatic capacitance Cx of a detection target into a charge quantity Qx corresponding to the electrostatic capacitance Cx of the detection target, and of supplementing with a charge quantity corresponding to the converted charge quantity Qx and performing integration; a comparison step of comparing an output of the CQ supplement step with a threshold voltage Vt; a sampling step of sampling an output of the comparison step and providing negative feedback to the CQ supplement step; and an arithmetic step of determining one of the electrostatic capacitance Cx of the detection target or change in electrostatic capacitance Cx based on sampling results of the sampling step.

Further, the CQ supplement means and the CQ supplement step are respectively accomplished by integrating part of the functions of the conventionally-used AD conversion means and AD conversion step with the conventionally-used CQ conversion means and CQ conversion step. To make a distinction from the conventional example, those means and step according to the present invention are respectively referred to as CQ supplement means and CQ supplement step.

According to the present invention, the CQ conversion means for converting an electrostatic capacitance into a charge quantity and 1-bit DA conversion means included in a delta-sigma type AD converter are integrated with each other, which makes it possible to reduce the number of circuit elements to reduce component cost. In particular, it becomes possible to realize the electrostatic capacitance detection circuit and the electrostatic capacitance detection method which are capable of detecting an electrostatic capacitance at high resolution with such a simpler configuration as to add passive elements to one input/output port of a general-purpose microcomputer.

### BRIEF DESCRIPTION OF THE DRAWINGS

In the accompanying drawings:

FIG. 1 is a block diagram illustrating an electrostatic capacitance detection circuit according to a first embodiment of the present invention;

FIG. 2 is a block diagram illustrating a conventional electrostatic capacitance detection circuit;

FIG. 3A is a diagram illustrating CQ supplement means according to the first embodiment or CV conversion means according to a second embodiment of the present invention;

FIG. 3B is a diagram illustrating another CQ supplement means according to the first embodiment or another CV conversion means according to the second embodiment;

FIG. 4A is a diagram illustrating another CQ supplement means according to the first embodiment or another CV conversion means according to the second embodiment;

FIG. 4B is a diagram illustrating another CQ supplement means according to the first embodiment or another CV conversion means according to the second embodiment;

FIG. 5 is a diagram illustrating a circuit configuration according to the first or second embodiment and a circuit configuration of an input/output port of a microcomputer according to the first or second embodiment;

FIG. 6 is a block diagram illustrating an electrostatic capacitance detection circuit according to the second embodiment of the present invention;

FIG. 7 is a timing chart illustrating a detection operation according to the second embodiment;

FIG. 8 is a timing chart illustrating an initialization operation according to the second embodiment;

FIG. 9 is a flow chart illustrating an electrostatic capacitance detection method according to the first embodiment of the present invention;

FIG. 10 is a flow chart illustrating an electrostatic capacitance detection method according to the second embodiment of the present invention;

FIG. 11 is a flow chart illustrating the initialization operation according to the second embodiment;

FIG. 12A is a configuration diagram of a one-dimensional electrostatic capacitance detection device according to the first or second embodiment; and

FIG. 12B is a configuration diagram of a two-dimensional electrostatic capacitance detection device according to the first or second embodiment.

### DETAILED DESCRIPTION OF THE PREFERRED EMBODIMENTS

### First Embodiment

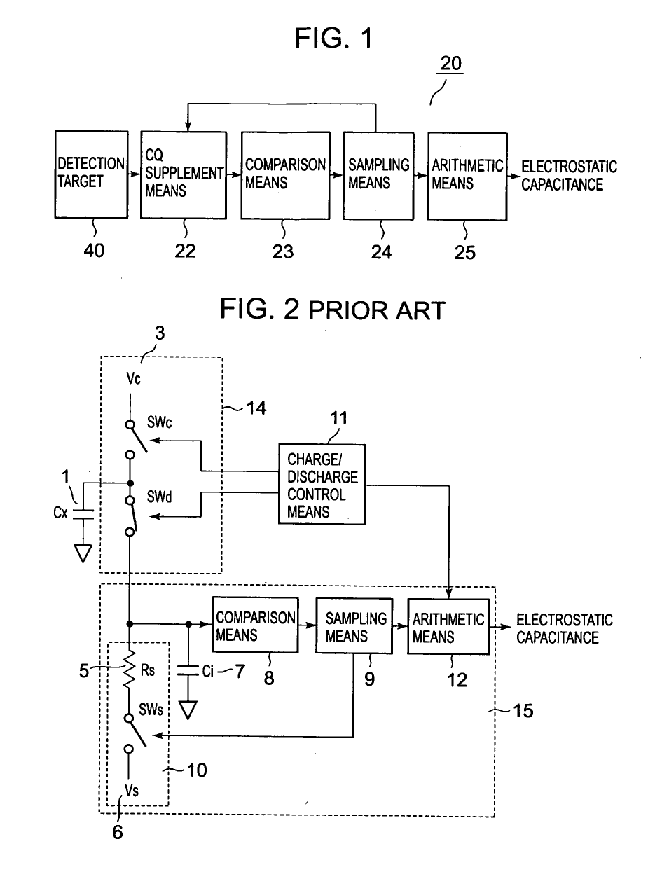

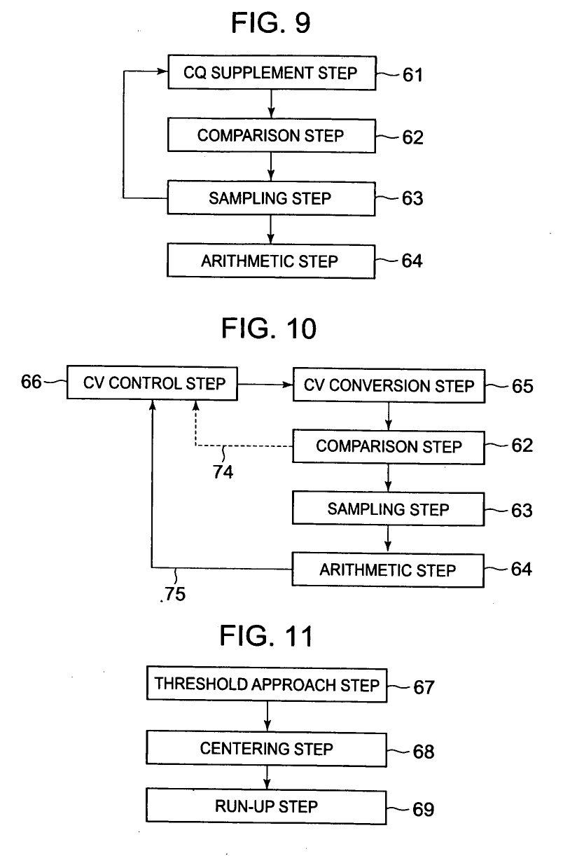

Referring to FIG. 1 and FIG. 9, a first embodiment of the present invention is described. An electrostatic capacitance detection circuit 20 according to the first embodiment of the present invention includes CQ supplement means 22 having functions of converting an electrostatic capacitance Cx of a detection target 40 into a charge quantity Qx corresponding to the electrostatic capacitance Cx and outputting the charge quantity Qx, and of supplementing with a charge quantity corresponding to the output charge quantity and performing integration, comparison means 23 for comparing an output of the CQ supplement means 22 with a threshold voltage Vt, sampling means 24 for sampling an output of the comparison means 23 and providing negative feedback to the CQ supplement means 22, and arithmetic means 25 for determining the electrostatic capacitance Cx of the detection target 40 or change in electrostatic capacitance Cx based on sampling results of the sampling means 24.

Further, an electrostatic capacitance detection method according to the first embodiment of the present invention is realized by including a CQ supplement step 61 of converting an electrostatic capacitance Cx of a detection target 40 into a charge quantity Qx corresponding to the electrostatic capacitance Cx and outputting the charge quantity Qx, and of supplementing with a charge quantity corresponding to the output charge quantity and performing integration, a comparison step 62 of comparing an output of the CQ supplement step 61 with a threshold voltage Vt, a sampling step 63 of sampling an output of the comparison step 62 and providing negative feedback to the CQ supplement step 61, and an arithmetic step 64 of determining the electrostatic capacitance Cx of the detection target 40 or change in electrostatic capacitance Cx based on sampling results of the sampling step 63.

Hereinafter, respective means and steps are described in detail.

The detection target 40 may be an electrostatic capacitance of a two-terminal capacitor, and may be a stray capacitance of an electrode or the like of an electrostatic capacitance detection device which detects approach of an object or a position thereof. In the case of detecting a position of an approaching object, a plurality of detection electrodes corresponding to coordinates to be detected are respectively associated with detection-target electrostatic capacitances. However, for convenience sake, description herein is mainly given of a case where one electrostatic capacitance is to be detected.

A preferred embodiment of the CQ supplement means 22 of the CQ supplement step 61 is illustrated in FIG. 1 and FIG. 9.

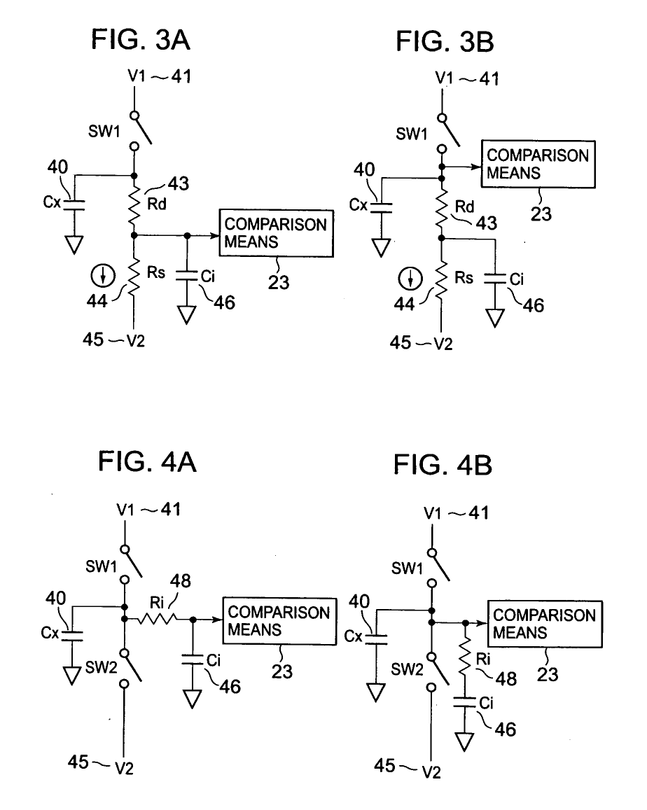

A circuit configuration of FIG. 3A is now described. One terminal of the detection target 40 is connected to a constant voltage source having, for convenience sake, an arbitrary value. Another terminal of the detection target 40 is connected to one terminal of a switch SW1 and to one terminal of a discharge resistor Rd 43. Another terminal of the switch SW1 is connected to a constant voltage source 41 having a voltage V1. Another terminal of the discharge resistor Rd 43 is connected to one terminal of a supplement resistor Rs 44 and to one terminal of an integration capacitor Ci 46. Outputs of the discharge resistor Rd 43 and the integration capacitor Ci 46 are connected to the comparison means 23. Another terminal of the supplement resistor Rs 44 is connected to a constant voltage source 45 having a voltage V2. Another terminal of the integration capacitor Ci 46 is connected to a constant voltage source having an arbitrary value, such as a ground. The switch SW1 is controlled by the sampling means 24.

Here, an electrostatic capacitance of the integration capacitor Ci 46 is large enough not to vary significantly, and a voltage thereof is controlled to be substantially equal to the threshold voltage Vt of the comparison means 23 of the comparison step 62.

Further, the voltage V1 of the constant voltage source 41 is set higher than the threshold voltage Vt of the comparison means 23 of the comparison step 62 while the voltage V2 of the constant voltage source 45 is set lower than the threshold voltage Vt of the comparison means 23 of the comparison step 62. However, the voltage setting is not limited to the above, and conversely the voltage V1 of the constant voltage source 41 may be set lower than the threshold voltage Vt of the comparison means 23 of the comparison step 62 while the voltage V2 of the constant voltage source 45 may be set higher than the threshold voltage Vt of the comparison means 23 of the comparison step 62.

The electrostatic capacitance Cx of the detection target 40 is charged from the constant voltage source 41 when the switch SW1 is turned on, and is discharged to the integration capacitor Ci 46 via the discharge resistor Rd 43 immediately after the switch SW1 has been turned off. In this way, through turning on/off of the switch SW1 Nc times, a charge quantity Qx expressed by Equation 1 is discharged from the electrostatic capacitance Cx to be charged in the integration capacitor Ci 46. The charge quantity Qx corresponds to a charge quantity that is input to a delta-sigma type AD converter.

Qₓ≈Cₓ×(V₁−Vᵢ)×N_{c} [Equation 1]

At the same time, in the CQ supplement means 22 of the CQ supplement step 61, in order to control the voltage of the integration capacitor Ci 46 to be substantially constant, the discharge resistor Rd 43 and the supplement resistor Rs 44 are connected to the integration capacitor Ci 46. The integration capacitor Ci 46 is supplemented with a charge quantity Qs, which is opposite in polarity and substantially equal in quantity to the charge quantity Qx from the electrostatic capacitance Cx of the detection target 40. Note that the polarity referred to here is defined with reference to the threshold voltage Vt of the comparison means 23 of the comparison step 62. Accordingly, when a determination time period is represented by Ts and a total period during which the switch SW1 is turned on is represented by Tc, the charge quantity Qs is expressed by Equation 2 and supplements the integration capacitor Ci 46. The supplement operation corresponds to an operation of a 1-bit DA converter in the delta-sigma type AD converter.

$${Q}_{s} \approx {T}_{c} \frac{( {V}_{1} - {V}_{t} )}{{R}_{d}} + {T}_{s} \frac{( {V}_{2} - {V}_{t} )}{{R}_{s}} \qquad [ Equation 2 ]$$

As described above, according to the first embodiment of the present invention, the switch for the CQ conversion and a switch serving as the 1-bit DA converter are integrated with each other, to thereby reduce the number of components.

The integration capacitor Ci 46 corresponds to integration means in the delta-sigma type AD converter, and performs integration on a charge quantity Qi, which corresponds to a supplement error of a quantity by which the charge quantity Qx from the electrostatic capacitance Cx of the detection target 40 has not been supplemented with the charge quantity Qs, to convert the charge quantity Qi into a voltage. The integration capacitor Ci 46 is used to accumulate the errors for reducing a cumulative error for charge supplement, and to convert the cumulative error for the charge quantity into a voltage. Specifically, because the voltage of the integration capacitor Ci 46 is controlled to be substantially constant, a sum of the charge quantity Qx from the electrostatic capacitance Cx of the detection target 40, which is expressed by Equation 1, and the charge quantity Qs for supplement, which is expressed by Equation 2, is controlled to be substantially zero. The voltage of the integration capacitor Ci 46 is output to the comparison means 23 of the comparison step 62.

It is natural that the voltage of the integration capacitor Ci 46 be directly output to the comparison means 23 of the comparison step 62, as illustrated in FIG. 3A. However, as illustrated in FIG. 3B, the voltage of the integration capacitor Ci 46 may be output to the comparison means 23 of the comparison step 62 via the discharge resistor Rd 43. In this case, the switch and the voltage comparison means are directly connected with each other, which makes it possible to realize the CQ supplement means 22 with such a simpler configuration as to merely add passive elements to, for example, one input/output port of a general-purpose microcomputer. Note that in this case, sampling made by the sampling means 24 of the sampling step 63 needs to be performed after the switch SW1 is turned off and then charges sufficiently migrate from the electrostatic capacitance Cx of the detection target 40 into the integration capacitor Ci 46.

In the comparison means 23 of the comparison step 62, the voltage output from the CQ supplement means 22 of the CQ supplement step 61 is compared with the threshold voltage Vt, and the comparison result is output to the sampling means 24 of the sampling step 63, to thereby convert the analogue voltage into a binary digital signal.

The binary digital signal obtained through the conversion made by the comparison means 23 of the comparison step 62 is sampled by the sampling means 24 of the sampling step 63. As to the sampling made by the sampling means 24 of the sampling step 63, a latch circuit may be used, and in the case of using a general-purpose input port of a microcomputer, port reading corresponds to the sampling.

As a result of the sampling, when the voltage of the integration capacitor Ci 46 is determined to be lower than the threshold voltage Vt, in order to increase the voltage of the integration capacitor Ci 46, the switch SW1 in the CQ supplement means 22 of the CQ supplement step 61 is turned on once. On the other hand, when the voltage of the integration capacitor Ci 46 is determined to be higher than the threshold voltage Vt, in order to decrease the voltage of the integration capacitor Ci 46, control is made such that the switch SW1 in the CQ supplement means 22 of the CQ supplement step 61 is not turned on. In this way, the switch SW1 in the CQ supplement means 22 of the CQ supplement step 61 is controlled by the sampling means 24, which makes it possible to control the voltage of the integration capacitor Ci 46 to be a value approximate to the threshold voltage Vt of the comparison means 23 of the comparison step 62.

Here, if a single turn-on period of the switch SW1 is excessively long, change in voltage of the integration capacitor Ci 46 caused by single turn-on of the switch SW1 becomes too large. Further, if an interval of the sampling is excessively long, the voltage of the integration capacitor Ci 46 changes largely because of charges which flow through the supplement resistor Rs 44 during the interval. To avoid those problems, an interval of the sampling and a single turn-on period of the switch SW1 need be set short enough to prevent the voltage of the integration capacitor Ci 46 from largely deviating from the threshold voltage Vt of the comparison means 23 of the comparison step 62, whereas no particular limitation is placed on timings of the sampling.

The arithmetic means 25 of the arithmetic step 64 uses the sampling results of the sampling means 24 of the sampling step 63 to obtain a digital value corresponding to the electrostatic capacitance Cx of the detection target 40 through arithmetic operations. In the arithmetic means 25 of the arithmetic step 64, by virtue of the above-mentioned fact that the sum of the charge quantity Qx from the electrostatic capacitance Cx of the detection target 40 and the charge quantity Qs for supplement is controlled to be substantially zero, the electrostatic capacitance Cx can be determined through, for example, Equation 3 by combining Equation 1 and Equation 2. Note that the determination time period Ts is set as a time period excluding a transient state of the integration capacitor Ci 46 in which the voltage thereof is not approximate to the threshold voltage Vt of the comparison means 23 of the comparison step 62, and excluding an initialization state thereof.

$${C}_{x} \approx \frac{1}{{N}_{c}} \{ \frac{{T}_{s} ( {V}_{t} - {V}_{2} )}{{R}_{s} ( {V}_{1} - {V}_{t} )} - \frac{{T}_{c}}{{R}_{d}} \} \qquad [ Equation 3 ]$$

For example, when the determination time period Ts is 100 μs, the number of times Nc the switch SW1 is turned on is 20, the total period Tc during which the switch SW1 is turned on is 20 μs, a resistance of the supplement resistor Rs 44 is 500 kΩ, a resistance of the discharge resistor Rd 43 is 200 kΩ, the voltage V1 of the constant voltage source 41 is 5.0V, the threshold voltage Vt of the comparison means 23 of the comparison step 62 is 2.5 V, and the voltage V2 of the constant voltage source 45 is 0 V, the electrostatic capacitance Cx is determined as 5 pF through Equation 3.

The case of determining the electrostatic capacitance Cx through Equation 3 has been described by way of example, but any method can be used as long as the electrostatic capacitance Cx is determined based on a relationship between Equation 1 and Equation 2.

Further, in a case where it is sufficient to determine a value corresponding to the electrostatic capacitance Cx of the detection target 40 instead of determining an accurate value of the electrostatic capacitance Cx thereof, the value can be determined by any way or method as long as the value corresponding to the electrostatic capacitance Cx of the detection target 40 is determined based on the output of the sampling means 24 of the sampling step 63. For example, there can be used a method of counting the number of times the switch SW1 is turned on during the determination time period Ts with the determination time period Ts, a total period during which the switch SW1 is turned on is represented by Tc, the resistance of the discharge resistor Rd 43, the resistance of the supplement resistor Rs 44, the voltage V1 of the constant voltage source 41, the threshold voltage Vt of the comparison means 23 of the comparison step 62, and the power source voltage V2 of the constant voltage source 41 being set as constants, and a method of detecting temporal transition of a digital value corresponding to the electrostatic capacitance Cx of the detection target 40 by means of a digital filter or the like while the detection is continuously performed.

The case where the CQ supplement means 22 of the CQ supplement step 61 is realized by the configuration illustrated in FIG. 3A or FIG. 3B has been described above by way of example, but the CQ supplement means 22 of the CQ supplement step 61 can be realized also by a configuration illustrated in FIG. 4A or FIG. 4B.

The circuit configuration of FIG. 4A is now described. One terminal of the detection target 40 is connected to a constant voltage source having, for convenience sake, an arbitrary value. Another terminal of the detection target 40 is connected to one terminal of the switch SW1, to one terminal of a switch SW2, and to one terminal of an integration resistor Ri 48. Another terminal of the switch SW1 is connected to the constant voltage source 41 having the voltage V1. Another terminal of the switch SW2 is connected to the constant voltage source 45 having the voltage V2. Another terminal of the integration resistor Ri 48 is connected to the comparison means 23 and to one terminal of the integration capacitor Ci 46. Another terminal of the integration capacitor Ci 46 is connected to a constant voltage source having an arbitrary value.

The configuration illustrated in FIG. 4A is accomplished by integrating the discharge resistor Rd 43 and the supplement resistor Rs 44 of the configuration illustrated in FIG. 3A to be the integration resistor Ri 48, and adding the switch SW2. As in the case of the switch SW1, the switch SW2 is also controlled by the sampling means 24.

Specifically, as a result of the sampling, when the voltage of the integration capacitor Ci 46 is determined to be lower than the threshold voltage Vt, in order to increase the voltage of the integration capacitor Ci 46, the switch SW1 in the CQ supplement means 22 of the CQ supplement step 61 is turned on once. On the other hand, when the voltage of the integration capacitor Ci 46 is determined to be higher than the threshold voltage Vt, in order to decrease the voltage of the integration capacitor Ci 46, control is made such that the switch SW2 in the CQ supplement means 22 of the CQ supplement step 61 is turned on once.

Further, in the configuration of FIG. 4A, due to the switch SW1 and the switch SW2, the electrostatic capacitance Cx of the detection target 40 is charged with different voltages, and charges discharged from the electrostatic capacitance Cx are subjected to integration by the integration capacitor Ci 46. Here, the configuration of FIG. 4A has one additional switch compared with the configuration of FIG. 3A. However, because the switch SW1 and the switch SW2 are used not to be turned on simultaneously with each other, when the control for the switches made by the sampling means 24 of the sampling step 63 is realized using an output port of a general-purpose microcomputer or the like, component cost is hardly affected in many cases, and therefore component cost can be reduced correspondingly to the eliminated resistor.

In the configurations of FIG. 4A and FIG. 4B, when the number of times the switch SW1 is turned on is represented by N1, the number of times the switch SW2 is turned on is represented by N2, a single turn-on period of the switch SW1 is represented by t1, and a single turn-on period of the switch SW2 is represented by t2, the charge quantity Qi is expressed by Equation 4 and flows through the integration capacitor Ci 46.

$${Q}_{i} \approx ( {C}_{x} + \frac{{t}_{1}}{{R}_{i}} ) {N}_{1} ( {V}_{1} - {V}_{t} ) + ( {C}_{x} + \frac{{t}_{2}}{{R}_{i}} ) {N}_{2} ( {V}_{2} - {V}_{t} ) \qquad [ Equation 4 ]$$

Here, when the voltage of the integration capacitor Ci 46 is controlled to be substantially equal to the threshold voltage Vt of the comparison means 23 of the comparison step 62, the charge quantity Qi is substantially zero in a steady state. Therefore, the electrostatic capacitance Cx of the detection target 40 in this case can be determined through Equation 5 solved for Cx by substituting zero for Qi of Equation 4.

$${C}_{x} \approx - \frac{\{ {t}_{1} {N}_{1} ( {V}_{1} - {V}_{t} ) + {t}_{2} {N}_{2} ( {V}_{2} - {V}_{t} ) \}}{{R}_{i} \{ {N}_{1} ( {V}_{1} - {V}_{t} ) + {N}_{2} ( {V}_{2} - {V}_{t} ) \}} \qquad [ Equation 5 ]$$

Note that if the single turn-on period t1 of the switch SW1 and the single turn-on period t2 of the switch SW2 are set as the same period t, Equation 6 obtained by substituting t for t1 and t2 of Equation 4 shows that zero is required within curly brackets “{ }”, which makes impossible to determine a value of Cx.

$$\begin{matrix}{Q}_{i} \approx 0 \\ = ( {C}_{x} + \frac{t}{{R}_{i}} ) {N}_{1} ( {V}_{1} - {V}_{t} ) + ( {C}_{x} + \frac{t}{{R}_{i}} ) {N}_{2} ( {V}_{2} - {V}_{t} ) \\ = ( {C}_{x} + \frac{t}{{R}_{i}} ) \{ {N}_{1} ( {V}_{1} - {V}_{t} ) + {N}_{2} ( {V}_{2} - {V}_{t} ) \}\end{matrix} \qquad [ Equation 6 ]$$

Therefore, in the present invention, the electrostatic capacitance Cx is detected by setting different values for the single turn-on period t1 of the switch SW1 during the determination time period and the single turn-on period t2 of the switch SW2 during the determination period so that a ratio of t1 to t2 becomes 1:0.7 or less or 1:1.5 or more.

For example, in a case where the single turn-on period t1 of the switch SW1 is 10 μs, the single turn-on period t2 of the switch SW2 is 1 μs, the number of times N1 the switch SW1 is turned on is 10, the number of times N2 the switch SW2 is turned on is 60, the resistance of the integration resistor Ri 48 is 100 kΩ, the voltage V1 of the constant voltage source 41 is 5.0 V, the threshold voltage Vt of the comparison means 23 of the comparison step 62 is 2.5 V, and the voltage V2 of the constant voltage source 45 is 0 V, the electrostatic capacitance Cx is determined as 8 pF by substituting those values into Equation 5. As in the examples of FIG. 3A and FIG. 3B, the way or method for determining a value corresponding to the electrostatic capacitance Cx is not limited to the above, and any way or method can be used as long as the electrostatic capacitance Cx is determined based on the operation of the CQ supplement means 22 of the CQ supplement step 61.

In the case of the configuration of FIG. 4A, the voltage of the integration capacitor Ci 46 is directly output to the comparison means 23 of the comparison step 62, and hence noise-resistant accurate detection can be made.

In the case of the configuration of FIG. 4B, the voltage of the integration capacitor Ci 46 is output to the comparison means 23 of the comparison step 62 via the integration resistor Ri 48, and hence the output is relatively susceptible to noise. Therefore, the sampling made by the sampling means 24 of the sampling step 63 needs to be performed after the switch SW1 or the switch SW2 is turned off and then a sufficient time has elapsed. On the other hand, a voltage of a connection point between the switch SW1 and the switch SW2 is directly output to the comparison means 23 of the comparison step 62.

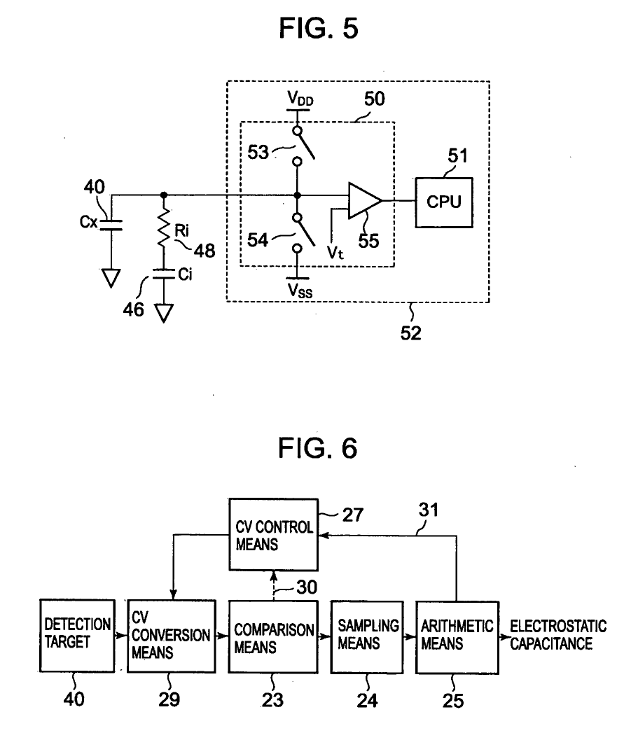

With this configuration, it becomes possible to determine the electrostatic capacitance Cx of the detection target 40 with such a simpler configuration as to merely add the integration resistor Ri 48 and the integration capacitor Ci 46 to, for example, one input/output port 50 of a general-purpose microcomputer 52 illustrated in FIG. 5.

A configuration of FIG. 5 is now described. In FIG. 5, one terminal of the detection target 40 is connected to a constant voltage source having, for convenience sake, an arbitrary value. Another terminal of the detection target 40 is connected to the input/output port 50 and to one terminal of the integration resistor Ri 48. Another terminal of the integration resistor Ri 48 is connected to one terminal of the integration capacitor Ci 46. Another terminal of the integration capacitor Ci 46 is connected to a constant voltage source such as a ground. The input/output port 50 is connected to a CPU 51 inside the microcomputer 52. An input/output terminal of the input/output port 50 is connected to the another terminal of the detection target 40 and to the one terminal of the integration resistor Ri 48. The input/output terminal is further connected to one terminal of a switch 53 and to one terminal of a switch 54. Another terminal of the switch 53 is connected to a constant voltage source VDD, and similarly another terminal of the switch 54 is connected to a constant voltage source VSS. A connection point between the one terminal of the switch 53 and the one terminal of the switch 54 is connected to a positive input of a comparator 55. A negative input of the comparator 55 is connected to the threshold voltage Vt, and an output of the comparator 55 is connected to the CPU 51.

Note that the integration resistor Ri 48 and the integration capacitor Ci 46 are connected in series, and it is needless to say that places of the integration resistor Ri 48 and the integration capacitor Ci 46 may be exchanged. In this configuration, the sampling means 24 of the sampling step 63 and the arithmetic means 25 of the arithmetic step 64 are realized using the CPU 51 included in the microcomputer 52.

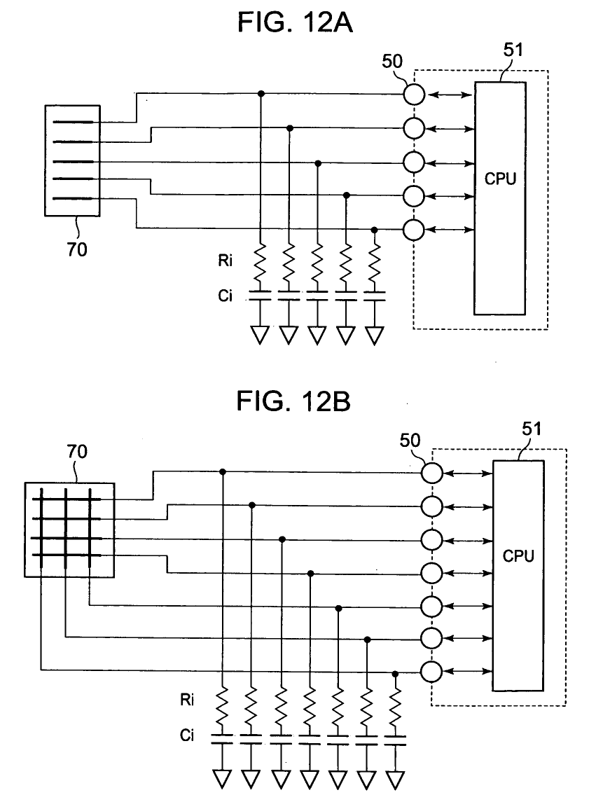

In this embodiment, as illustrated in FIG. 12A, electrostatic capacitances of a plurality of detection electrodes which are arranged on a support substrate 70 in a one-dimensional direction are connected with a plurality of ports of the same microcomputer, which makes it possible to constitute a slider which detects approach of an object and a position thereof in the one-dimensional direction based on values respectively corresponding to the electrostatic capacitances of the detection electrodes. In FIG. 12A, each of interconnects for the support substrate 70 and the input/output ports 50 is connected with one terminal of each integration resistor Ri. Another terminal of each integration resistor Ri is connected to one terminal of each integration capacitor Ci. Another terminal of each integration capacitor Ci is connected to a constant voltage source, but this is merely an embodiment.

Further, as illustrated in FIG. 12B, by arranging detection electrodes corresponding to two-dimensional coordinates on a support substrate 70, it becomes possible to constitute an electrostatic capacitance detection device which detects approach of an object and a position thereof in a two-dimensional direction in a similar manner to the above. Also in the case of FIG. 12B, each of interconnects for the support substrate 70 and the input/output ports 50 is connected with one terminal of each integration resistor Ri. Another terminal of each integration resistor Ri is connected to one terminal of each integration capacitor Ci. Another terminal of each integration capacitor Ci is connected to a constant voltage source.

According to the embodiment described above, with a relatively simpler configuration with low component cost, an electrostatic capacitance can be detected at such high resolution as in the case of the delta-sigma type AD converter.

### Second Embodiment

In the first embodiment, the example in which the delta-sigma type AD converter is applied has been described. However, with regard to an electrostatic capacitance to be detected in the case of detecting approach of an object, coordinates of the approaching object, or the like, a value of an electrostatic capacitance when the object is not approaching is often so large that change in electrostatic capacitance caused by the approach of the object is relatively small. As a result, resolution with respect to the change in electrostatic capacitance to be detected is relatively lowered. It is possible to increase the number of sampling times to further improve resolution, but in this case, a period required for the AD conversion becomes longer. Alternatively, a method of using a reference capacitor Cr to cancel the influence of an offset capacitance may be employed, but in this case, there arises a problem of high component cost.

A second embodiment of the present invention has an object of realizing an electrostatic capacitance detection circuit and an electrostatic capacitance detection method which are capable of detecting change in electrostatic capacitance Cx of the detection target 40 at high speed and high resolution with a simple configuration similar to that of the first embodiment. Each of the electrostatic capacitance detection circuit and the electrostatic capacitance detection method does not determine an accurate value of an electrostatic capacitance of the detection target 40, but is capable of detecting a value corresponding to change in electrostatic capacitance at high resolution.

Referring to FIG. 6 and FIG. 10, a preferred example of the second embodiment is described. FIG. 6 relates to electrostatic capacitance detection means according to the second embodiment. The electrostatic capacitance detection means is realized by including CV conversion means 29 for converting an electrostatic capacitance of the detection target 40 into a voltage waveform corresponding to the electrostatic capacitance, comparison means 23 for comparing an output of the CV conversion means 29 with a threshold voltage, CV control means 27 for controlling the CV conversion means 29 so that a DC component of the voltage waveform output from the CV conversion means 29 changes in correspondence with the electrostatic capacitance of the detection target 40 and that the threshold voltage of the comparison means 23 falls within a variation range of an AC component of the voltage waveform, sampling means 24 for sampling an output of the comparison means 23, and arithmetic means 25 for determining a value corresponding to the electrostatic capacitance of the detection target 40 based on an output of the samplingmeans 24. The CV control means 27 is controlled by the arithmetic means 25. Alternatively, the CV control means 27 may be controlled based on an output of the comparison means 23 in an initialization stage. The former case is indicated by a solid line 31 of FIG. 6, and the latter case is indicated by a dotted line 30 of FIG. 6. A difference between this example of the second embodiment and the conventional example resides in that, in the second embodiment, a result made by the arithmetic means 25 is output to the CV conversion means 29 to control a voltage to be output from the CV conversion means 29, whereas in the conventional example, the voltage is controlled by the charge/discharge control means 11 at a predetermined timing, and the control result is output to the arithmetic means 12. The difference therebetween also resides in that the charge/discharge control means 11 of the conventional example has the function of merely controlling the voltage, whereas in this example of the second embodiment, the function of controlling the voltage is integrated with a function of controlling the CV conversion.

Further, referring to FIG. 10, an electrostatic capacitance detection method according to the second embodiment is described. The electrostatic capacitance detection method is realized by including a CV conversion step 65 of converting an electrostatic capacitance of the detection target 40 into a voltage waveform corresponding to the electrostatic capacitance, a comparison step 62 of comparing an output of the CV conversion step 65 with a threshold voltage, a CV control step 66 of controlling the CV conversion step 65 so that a DC component of the voltage waveform output in the CV conversion step 65 changes in correspondence with the electrostatic capacitance of the detection target 40 and that the threshold voltage of the comparison step 62 falls within a voltage waveform variation range of an AC component of the voltage waveform, a sampling step 63 of sampling an output of the comparison step 62, and an arithmetic step 64 of determining a value corresponding to the electrostatic capacitance of the detection target 40 based on an output of the sampling step 63. The CV control step 66 is carried out based on an output of the arithmetic step 64 as indicated by a solid line 75. In an initialization state, the CV control step 66 may be carried out based on an output of the comparison step 62 as indicated by a dotted line 74.

Hereinafter, respective means and steps are described in detail.

The electrostatic capacitance Cx of the detection target 40 is defined similarly to the first embodiment. However, because it is change in electrostatic capacitance Cx that is to be detected in the second embodiment, for convenience sake, an electrostatic capacitance of the detection target 40 in a case where an object is not approaching is represented by Cx, and an increase amount of the electrostatic capacitance caused by the approach of the object is represented by dCx. The case where the change dCx in electrostatic capacitance Cx is detected at high resolution is described by way of example.

In the second embodiment, operations different from those of the delta-sigma type AD converter are performed, and hence means and step identical with the CQ supplement means 22 and CQ supplement step 61 illustrated in FIG. 3A, 3B, 4A, or 4B according to the first embodiment are referred to as the CV conversion means 29 and the CV conversion step 65, respectively. Note that the switch SW1 and the switch SW2 in the CV conversion means 29 of the CV conversion step 65 are turned on/off based not on sampling results of the sampling means 24 of the sampling step 63, but on the control of the CV control means 27 of the control step 66.

The comparison means 23 of the comparison step 62 and the sampling means 24 of the sampling step 63 are substantially identical with those of the first embodiment. In other words, the comparison means 23 of the comparison step 62 compares a voltage of the integration capacitor Ci with the threshold voltage Vt, to thereby perform binarization. Further, the sampling means 24 of the sampling step 63 performs sampling using a latch circuit or the like. Note that the sampling means 24 of the sampling step 63 merely samples the output of the comparison means 23 of the comparison step 62 without controlling the switches in the CV conversion means 29 of the CV conversion step 65.

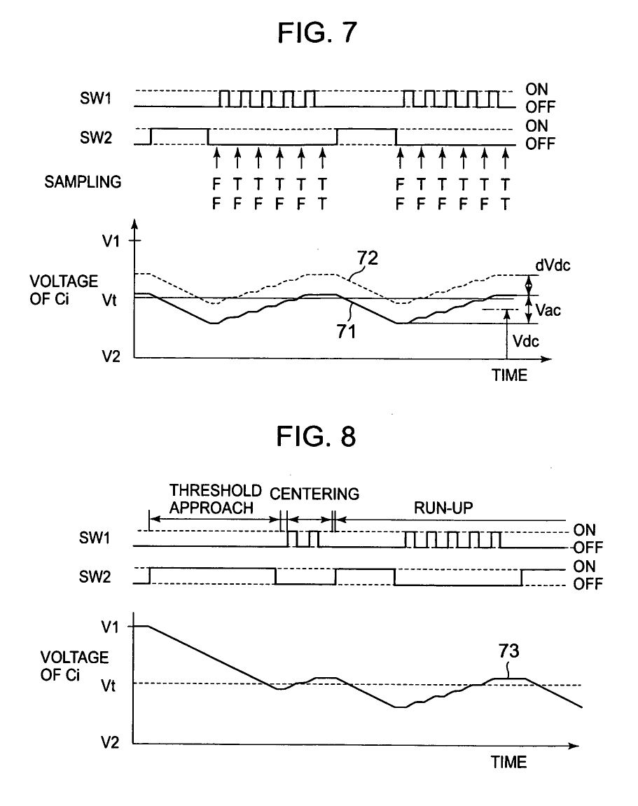

Hereinafter, as a preferred example, detailed description is mainly given of an operation of the CV control means 27 of the CV control step 66 in the case of using the CV conversion means 29 of the CV conversion step 65 illustrated in FIG. 4A or 4B with reference to a timing chart of FIG. 7.

SW1 and SW2 illustrated in the timing chart of FIG. 7 respectively indicate an on/off state of the switch SW1 and the switch SW2. A vertical axis of the timing chart for SW1 and SW2 indicates the on/off state, in which upper straight lines show the on state while lower straight lines show the off state. A horizontal axis thereof indicates time. Each of upward arrows (↑) in the section of sampling indicates a sampling timing. “T” and “F” illustrated below the upward arrow (↑) respectively represent “True” and “False”, and in the case of positive logic, “True” indicates a state in which the voltage of the integration capacitor Ci is higher than the threshold voltage Vt whereas “False” indicates a state in which the voltage of the integration capacitor Ci is lower than the threshold voltage Vt. In the case of negative logic, “True” and “False” indicate states conversely to the above. In a graph illustrated in the lower part of FIG. 7, a vertical axis indicates the voltage of the integration capacitor Ci, a horizontal axis indicates an elapsed time, a solid line indicates temporal change of a voltage waveform 71 in a case where an electrostatic capacitance of the detection target is Cx, and a dotted line indicates temporal change of a voltage waveform 72 in a case where an electrostatic capacitance of the detection target is Cx+dCx. The horizontal axis of FIG. 7 is a common time axis for all of SW1, SW2, sampling, and voltage change.

FIG. 7 illustrates an example of a steady state in which the switch SW1 is turned on/off five times as much as the switch SW2 is. Each of the voltage waveforms of the integration capacitor Ci gradually comes closer to the voltage V2 of the constant voltage source 45 while the switch SW2 is turned on, and to the voltage V1 of the constant voltage source 41 while the switch SW1 is turned on. Assuming the case where the CV conversion means 29 of FIG. 6 is used, sampling is performed by the sampling means while both of the switch SW1 and the switch SW2 are turned off under the situation in which the voltage of the integration capacitor Ci changes. Based on the number of “T”s obtained as a result of the sampling for one cycle, the arithmetic means 25 can grasp increase/decrease in electrostatic capacitance of the detection target 40. In a case where the sampling is performed six times for one cycle, as to the voltage waveform 71 in the case where the electrostatic capacitance of the integration capacitor Ci is Cx, the number of “T”s is one and the number of “F”s is five. On the other hand, as to the voltage waveform 72 in the case where the electrostatic capacitance of the integration capacitor Ci is Cx+dCx, the number of “T”s is five and the number of “F”s is one. As to the voltage waveform 71, such information that “T” is detected once out of six. As to the voltage waveform 72, such information that “T” is detected five times out of six. Based on the detection ratio of “T”, information received by the detection target 40 can be digitized to be output in the form of electrostatic capacitance from the arithmetic means 25 to an outside. When the electrostatic capacitance of the detection target 40 increases by dCx, the voltage waveform shifts substantially parallel with the voltage waveform 71 so as to come closer to the voltage V1 of the constant voltage source 41, which is provided on a side of the switch SW1 having the larger number of on/off times. On this occasion, the voltage waveforms 71, 72 are controlled as to include the threshold voltage Vt.

In FIG. 7, it is effective for the CV control means 27 of the CV control step 66 to control the switch SW1 and the switch SW2 in the CV conversion means 29 of the CV conversion step 65 to be turned on/off for such different periods that a ratio of the single turn-on period of the switch SW1 to the single turn-on period of the switch SW2 becomes 1:0.7 or less or 1:1.5 or more. As described in the first embodiment, this is because the electrostatic capacitance Cx of the detection target 40 and the voltage of the integration capacitor Ci 46 have no relationship to each other in the case where the single turn-on period of the switch SW1 is equal to the single turn-on period of the switch SW2 in the CV conversion means 29 of the CV conversion step 65 illustrated in FIG. 4A or FIG. 4B.

For example, in a case where the threshold voltage Vt is set to an intermediate value between the constant voltages V1 and V2, in order to control the voltage of the integration capacitor Ci 46 to fall within a predetermined range, if the single turn-on period t2 of the switch SW2 is longer than the single turn-on period t1 of the switch SW1, adjustment is made such that, for example, the number of times N1 the switch SW1 is turned on is conversely set larger than the number of times N2 the switch SW2 is turned on.

Through on/off of the switch SW1 and the switch SW2, an AC voltage with an amplitude of Vac generates across the integration capacitor Ci 46. In a case where a value of the amplitude Vac of the AC component is sufficiently small, the voltage of the integration capacitor Ci 46 is substantially equal to a DC component Vdc. Accordingly, the AC component Vac can be obtained through Equation 7 based on the single turn-on period t2 of the switch SW2 in the case where the single turn-on period t2 of the switch SW2 is longer than the single turn-on period t1 of the switch SW1. The same applies to the case where the single turn-on period t1 of the switch SW1 is longer than the single turn-on period t2 of the switch SW2. Note that compared to a value of the electrostatic capacitance Cx of the detection target 40, a value of the integration capacitor Ci is sufficiently large, and hence the influence of Cx is neglected.

$${V}_{ac} \approx {t}_{2} \frac{\vert {V}_{2} - {V}_{dc} \vert}{{R}_{i} {C}_{i}} \qquad [ Equation 7 ]$$

In the case where the AC component Vac of the voltage waveform of the integration capacitor Ci 46 is sufficiently smaller similarly to the above case, from input/output balance of charges into/from the integration capacitor Ci 46, Equation 8 is established by the DC component Vdc of the voltage waveform of the integration capacitor Ci 46, the total period T1 during which the switch SW1 is turned on, the total period T2 during which the switch SW2 is turned on, the number of times N1 the switch SW1 is turned on, the number of times N2 the switch SW2 is turned on, and the resistance of the integration resistor Ri 48.

$$( {C}_{x} {N}_{1} + \frac{{T}_{1}}{{R}_{1}} ) ( {V}_{1} - {V}_{dc} ) + ( {C}_{x} {N}_{2} + \frac{{T}_{2}}{{R}_{i}} ) ( {V}_{2} - {V}_{dc} ) = 0 \qquad [ Equation 8 ]$$

Equation 9 is obtained by solving Equation 8 for the DC component Vdc of the voltage of integration capacitor Ci 46.

$${V}_{dc} = \frac{{V}_{1} ( {C}_{x} {N}_{1} + \frac{{T}_{1}}{{R}_{i}} ) + {V}_{2} ( {C}_{x} {N}_{2} + \frac{{T}_{2}}{{R}_{i}} )}{( {C}_{x} {N}_{1} + \frac{{T}_{1}}{{R}_{i}} ) + ( {C}_{x} {N}_{2} + \frac{{T}_{2}}{{R}_{i}} )} \qquad [ Equation 9 ]$$

When the electrostatic capacitance of the detection target 40 increases from Cx to Cx+dCx, the DC component Vdc changes so as to come closer to the power source voltage on the side of the switch which is turned on/off a larger number of times, as illustrated in FIG. 7. A variation amount of the voltage of the integration capacitor Ci 46 is referred to as dVdc.

To detect the variation dVdc of the DC component due to the variation dCx of the electrostatic capacitance Cx of the detection target 40, the CV control means 27 of the CV control step 66 turns on and off the switch SW1 and the switch SW2 so that the above-mentioned AC component Vac and DC component Vdc of the voltage of the integration capacitor Ci 46 are set to desired values.

The sampling means 24 of the sampling step 63 may perform the sampling, for example, only after the switch SW1 is turned off, but in this embodiment, the sampling is performed after the switch SW1 or the switch SW2 is turned off as illustrated in FIG. 7. During the sampling, the voltage of the integration capacitor Ci 46 gradually changes, which means that the amplitude Vac of the AC component of the voltage of the integration capacitor Ci 46 substantially corresponds to a width of a detection range. And, the DC component Vdc of the voltage of the integration capacitor Ci 46 corresponds to a center of the detection range, and hence offset of the detection range can be set by setting the DC component Vdc. Specifically, the DC component Vdc of the voltage of the integration capacitor Ci 46 is set so that the threshold voltage Vt of the comparison means 23 of the comparison step 62 falls within a variation range of the voltage of the integration capacitor Ci 46 even when the electrostatic capacitance of the detection target 40 changes from Cx to Cx+dCx.

For example, in a case where the voltage V1 of the constant voltage source 41 is 5.0 V, the voltage V2 of the constant voltage source 45 is 0 V, the number of times N1 the switch SW1 is turned on for one cycle is 40, the number of times N2 the switch SW2 is turned on for one cycle is 8, the total period T1 during which the switch SW1 is turned on for one cycle is 40 μs, the total period T2 during which the switch SW2 is turned on for one cycle is 74 μs, the resistance of the integration resistor Ri 48 is 20 kΩ, and the electrostatic capacitance Cx of the detection target 40 is 50 pF, the DC component Vdc of the voltage of the integration capacitor Ci 46 is determined as 2.469 V by substituting those values into Equation 9. Because the total period T2 during which the switch SW2 is turned on for one cycle is separately input in eight times, the single turn-on period t2 of the switch SW2 is 9.25 μs. In a case where the capacitance of the integration capacitor Ci 46 is 15 nF, the amplitude Vac of the AC component of the voltage of the integration capacitor Ci 46 under these conditions is determined as 76 mV by substituting those values into Equation 7. Therefore, the voltage of the integration capacitor Ci 46 changes within a range from 2.431 V to 2.507 V.

When the electrostatic capacitance Cx of the detection target 40 increases to 55 pF, the DC component Vdc of the voltage of the integration capacitor Ci 46 is determined as 2.518 V by substituting the values into Equation 9, and accordingly the amplitude Vac of the AC component is determined as 78 mV. Therefore, the voltage of the integration capacitor Ci 46 changes within a range from 2.479 V to 2.557 V.

On this occasion, in a case where the threshold voltage Vt of the comparison means 23 of the comparison step 62 is 2.500 V, even when the electrostatic capacitance Cx of the detection target 40 changes from 50 pF to 55 pF, the change in electrostatic capacitance Cx of the detection target 40 can be detected based on results of the sampling made by the sampling means 24 of the sampling step 63 because the threshold voltage Vt falls within the variation range of the voltage of the integration capacitor Ci 46.

In this case, the width of the detection range is maintained substantially constant in a range of from 76 mV to 78 mV in correspondence with the amplitude Vac of the AC component of the voltage of the integration capacitor Ci 46, and the DC component Vdc of the voltage of the integration capacitor Ci 46 changes by 49 mV from 2.469 V to 2.518 V. Therefore, the change in electrostatic capacitance Cx of the detection target 40 is detected using approximately 63% of the detection range.

It is found from Equation 7 and Equation 9 that the electrostatic capacitance Ci of the integration capacitor Ci 46 affects by only the AC component Vac without affecting by the DC component Vdc of the voltage thereof, and hence the width of the detection range can be adjusted by setting the electrostatic capacitance of the integration capacitor Ci 46. The adjustment of the width of the detection range is not limited to the above, and may be performed by setting each of the single turn-on periods of the switches or the value of the integration resistor Ri 48 which affect the AC component Vac of the voltage of the electrostatic capacitance Ci of the integration capacitor Ci 46.

Further, the offset of the detection can be adjusted through, for example, Equation 9, by setting the total period during which the switch, which has been turned on for a longer period, is turned on for one cycle. The adjustment of the offset is performed when the electrostatic capacitance Cx in the case where an object is not approaching changes due to temperature change or the like. In the above-mentioned example in which the electrostatic capacitance Cx of the detection target 40 is 50 pF, when the total period during which the switch SW2 is turned on for one cycle is changed from 74 μs to 75 μs, the DC component Vdc of the voltage of the integration capacitor Ci 46 changes by 15 mV from 2.469 V to 2.454 mV. Therefore, when the total turn-on period for one cycle is changed on a 1 μs basis, the offset of the detection can be set with accuracy of approximately 15 mV. The adjustment of the offset of the detection is not limited to the above, and may be performed by setting other variable values included in the right side of Equation 9 for determining the DC component Vdc of the voltage of the integration capacitor Ci 46.

Next, the above-mentioned cycle of the switch control made by the CV control means 27 of the CV control step 66 is described. The cycle refers to an on/off sequence of the switch according to the same procedure. During one cycle, the switch SW1 and the switch SW2 are turned on/off once or a plurality of times.

In order to prevent the amplitude Vac of the AC component of the voltage of the integration capacitor Ci 46 from being larger, the on/off of the switch SW1 and the on/off of the switch SW2 are respectively normally controlled so as not to become unbalanced but to be uniform as much as possible. For example, in the case where the number of times the switch SW1 is turned on for one cycle is 40 and the number of times the switch SW2 is turned on for one cycle is 8 μs in the above-mentioned example, the switch SW1 is turned on/off five times each time the switch SW2 is turned on/off once.

In the case where the total period during which the switch SW1 is turned on for one cycle is 40 μs and the number of times the switch SW1 is turned on is 40 μs described above, the same period of 1 μs may be set as each single turn-on period of the switch SW1. On the other hand, in the case where the total period during which the switch SW2 is turned on for one cycle is 74 μs, the number of times the switch SW2 is turned on for one cycle cannot be divisible by 8. Accordingly, in the case where the turn-on period can be set only on, for example, the 1 μs basis, six turn-on periods of 9 μs and two turn-on periods of 10 μs are set so that the turn-on periods are made uniform as much as possible.

Next, detailed description is given of detection resolution.

It is normal to consider that the detection resolution corresponds to the number of sampling times for one cycle. But, in actuality, if sampling is performed a plurality of times by the sampling means 24 of the sampling step 63 with the integration capacitor Ci 46 having the same voltage, the number of voltages of the integration capacitor used during the sampling is reduced or becomes unbalanced, resulting in lowered detection resolution. For example, as described above, in the case where six turn-on periods of 9 μs and two turn-on periods of 10 μs are set for the switch SW2 for one cycle, if the periods during which the switch SW2 is turned on for the first time and for the fifth time are each set as 10 μs while the periods for the remaining times are each set as 9 μs, the same control is repeated twice. This is because the switch control for the first to fourth times and the switch control for the fifth to eighth times are made completely the same. However, under a noise environment, even when the same voltage is applied, different detection results are obtained, which maintains resolution. Under an environment where noise does not exist at all, resolution is reduced by half.

Then, some ways to prevent resolution from being lowered are described.

First, by setting a minimum unit for repetition not to be small, resolution is suppressed from being lowered. In the above-mentioned example, when a minimum unit for repetition is set not to be small by changing the periods by one, that is, by setting, for example, each of the periods during which the switch SW2 is turned on for the first time and for the sixth time as 10 μs while setting each of the periods for the remaining times as 9 μs, sampling is less likely to be performed with the same voltage as in other samplings. Therefore, even in the case where the total turn-on period for one cycle is divisible by the number of turn-on times for one cycle, all of the turn-on periods for one cycle are often desired not to be the same.

Further, when appropriate noise is superimposed on any one of the electrostatic capacitance Cx of the detection target 40, the CV conversion means 29 of the CV conversion step 65, and the comparison means 23 of the comparison step 62, the probability of sampling with the integration capacitor Ci 46 having the same voltage may be lower, which may improve detection resolution because of the noise. Note that when a noise level is too high, in order to eliminate the influence of noise, a plurality of cycles may be repeated for detection correspondingly to the noise level.

Further, it is also effective to actively applying such noise as an arbitrary waveform, for example, a ramp waveform to the voltage of the integration capacitor Ci 46. In the case of detecting electrostatic capacitances of the plurality of detection electrodes, stable noise can be applied with relatively lower cost by applying a single ramp waveform by means of capacitive coupling with interconnects or interconnect patterns.

In the above-mentioned example, the case where the electrostatic capacitance Cx of the detection target 40, the increase amount dCx of the electrostatic capacitance Cx, the voltage V1 of the constant voltage source 41, the voltage V2 of the constant voltage source 45, the threshold voltage Vt of the comparison means 23 of the comparison step 62, the resistance of the integration resistor Ri 48, and the capacitance of the integration capacitor Ci 46 are accurate values has been described. Even when there are variations in those values, the fundamental operation is similar to that of the above-mentioned example. By setting wider the detection range taking the variations thereof into consideration or by adjusting the range of Vac, which is the amplitude of the voltage of the integration capacitor Ci 46, based on arithmetic results of the arithmetic means 25 of the arithmetic step 64 as indicated by the solid line 31 of FIG. 6 and the solid line 75 of FIG. 10, change in electrostatic capacitance for detection of an approaching object can be grasped satisfactorily for practical purposes. For example, in the case where the object is not approaching, the turn-on periods of the switches in the CV conversion means 29 of the CV conversion step 65 may be changed by the CV control means 27 of the CV control step 66 so as to obtain a desired value from the arithmetic results of the arithmetic means 25 of the arithmetic step 64.

Substantially similarly to the case of the first embodiment, the arithmetic means 25 of the arithmetic step 64 uses the sampling results of the sampling means 24 of the sampling step 63 to obtain a digital value corresponding to the electrostatic capacitance Cx of the detection target 40 through arithmetic operations. The digital value corresponds to a final output of the electrostatic capacitance detection device of the present invention, and is a value determined by digitizing the change in electrostatic capacitance of the detection target 40. Note that it is not an accurate value of the electrostatic capacitance Cx of the detection target 40 but a value corresponding to change in electrostatic capacitance Cx that is determined in the second embodiment.

Therefore, in the arithmetic means 25, outputs of the sampling means 24 are counted. For example, by counting the number of sampling results in the case of positive logic for a predetermined number of cycles, a digital value corresponding to the electrostatic capacitance Cx can be obtained. It is needless to say that a digital value corresponding to the electrostatic capacitance Cx can be obtained also by counting the number of sampling results in the case of negative logic. Detection resolution can be improved by increasing the number of cycles for counting.

Further, in the arithmetic means 25, any way or method can be used as long as a value corresponding to the electrostatic capacitance Cx of the detection target 40 is determined based on the output of the sampling means 24 of the sampling step 63. For example, there can be used a method of detecting temporal transition of a digital value corresponding to change in electrostatic capacitance of the detection target 40 by means of a digital filter or the like based on sampling results so that continuous detection can be performed.

The operation in the steady state has been described above. Hereinafter, a preferred example of an initialization method for shifting the integration capacitor Ci 46 from an initialization state before detection to the steady state is described with reference to a timing chart of FIG. 8 and a flow chart of FIG. 11 for shifting the integration capacitor Ci 46 from the initialization state to the steady state.

For the initialization, threshold approach, centering, and run-up are performed as needed before detection of an electrostatic capacitance of the detection target 40 so as to make the integration capacitor Ci 46 become closer to the steady state. SW1 and SW2 illustrated in the timing chart of FIG. 8 respectively indicate an on/off state of the switch SW1 and the switch SW2. A vertical axis of the timing chart for SW1 and SW2 indicates the on/off state, in which upper straight lines show the on state while lower straight lines show the off state. A horizontal axis thereof indicates time. In a graph illustrated in the lower part of FIG. 8, a vertical axis indicates the voltage of the integration capacitor Ci, a horizontal axis indicates an elapsed time, and a solid line indicates temporal change of the voltage of the integration capacitor Ci. The horizontal axis of FIG. 8 is a common time axis for all of SW1, SW2, and voltage change. A period during which turn-on of the switch SW2 for the first time is called “threshold approach”, a period during which the switch SW1 is turned on/off repeatedly a predetermined number of times is called “centering”, and a period from a timing at which the switch SW2 starts to be turned on for the second time is called “run-up”. The threshold approach, the centering, and the run-up indicate periods.

Description is given with reference to FIG. 11. In a threshold approach step 67, the voltage of the integration capacitor Ci 46 is made approximate to the threshold voltage of the comparison means 23 of the comparison step 62. Specifically, when the voltage of the integration capacitor Ci 46 is higher than the threshold voltage Vt of the comparison means 23 of the comparison step 62, the switch to which the constant voltage source having a voltage lower than the threshold voltage Vt is connected is continuously turned on until comparison output is changed. On the other hand, when the voltage of the integration capacitor Ci 46 is lower than the threshold voltage Vt of the comparison means 23 of the comparison step 62, the switch to which the constant voltage source having a voltage higher than the threshold voltage Vt is connected is continuously turned on until comparison output is changed.

In a centering step 68, in order to adjust the voltage of the integration capacitor Ci 46 at the substantially center of the detection range, the switch, of which the single turn-on period is shorter and which is turned on/off repeatedly, is turned on/off for the number of times which is about half of that in the normal state. Alternatively, the switch, of which the single turn-on period is longer, may be turned on for a period which is half of the turn-on period in the steady state. For example, in the case of the second embodiment, the number of times the switch SW1 is turned on/off is halved compared with the normal state, or the switch SW2 is turned on for a period which is half of the turn-on period in the steady state from a timing at which the voltage of the integration capacitor Ci 46 is decreased to be lower than the threshold voltage Vt.

In a run-up step 69, the switches in the CV conversion means 29 of the CV conversion step 65 are turned on/off for the same cycles as in the case of actual detection so that the integration capacitor Ci 46 becomes closer to the steady state.

Hereinafter, an operation and effect of the run-up are described in detail.

In a case where the voltage of the integration capacitor Ci 46 deviates by a voltage dV from the voltage Vdc in the steady state, when a quantity of charges of the integration capacitor Ci 46 which changes during one cycle is represented by dQ, Equation 10 is established. Note that for convenience sake, change in voltage of the integration capacitor Ci 46 caused during one cycle is neglected.

$$( {C}_{x} {N}_{1} + \frac{{T}_{1}}{{R}_{i}} ) ( {V}_{1} - {V}_{dc} + d V ) + ( {C}_{x} {N}_{2} + \frac{{T}_{2}}{{R}_{i}} ) ( {V}_{2} - {V}_{dc} + d V ) = d Q \qquad [ Equation 10 ]$$

Equation 8 in the steady state is subtracted from Equation 10, to thereby obtain Equation 11.

$$\{ ( {C}_{x} {N}_{1} + \frac{{T}_{1}}{{R}_{i}} ) + ( {C}_{x} {N}_{2} + \frac{{T}_{2}}{{R}_{i}} ) \} d V = d Q \qquad [ Equation 11 ]$$

Here, under the same conditions as the above-mentioned example that the number of times N1 the switch SW1 is turned on for one cycle is 40, the number of times N2 the switch SW2 is turned on for one cycle is 8, the total period T1 during which the switch SW1 is turned on for one cycle is 40 μs, the total period T2 during which the switch SW2 is turned on for one cycle is 74 μs, the resistance of the integration resistor Ri 48 is 20 kΩ, and the electrostatic capacitance Cx of the detection target 40 is 50 pF, and in a case where the voltage deviation dV from the steady state is 1 V, the change dQ in charges of the integration capacitor Ci 46 is determined as 8,100 pC by substituting those values into Equation 11. As in the above-mentioned case, in the case where the capacitance of the integration capacitor Ci 46 is 15 nF, the change in voltage of the integration capacitor Ci 46 is determined as 0.54 V. In other words, roughly speaking, the voltage deviation from the steady state is reduced by half for each cycle so that the voltage of the integration capacitor Ci 46 approaches the steady state according to an exponential curve.

For example, it is assumed that, under a condition where absolute detection accuracy of about 1/64 (6 bits) is required, absolute detection accuracy becomes close to substantially ½ after the centering. In a case where the voltage deviation is reduced by half for every one cycle of the run-up, the run-up is performed for about five cycles taking into consideration the fact that the voltage of the integration capacitor Ci 46 approaches the steady state also during subsequent detection operations.

Note that in a case where it is sufficient to make relative comparison to determine relative change in electrostatic capacitance under the same condition, the run-up is not necessarily required, and, taking detection speed and power consumption into consideration, the required number of cycles may be performed as necessary. Complete convergence is not necessarily required as long as the voltage of the integration capacitor Ci 46 falls within a range permissible for the influence on detection results.

In a case where the voltage of the integration capacitor Ci 46 has been maintained in the steady state after the previous detection, it is not necessary to perform initialization each time detection is made. Therefore, in actuality, intervals of about 10 ms to several 10 ms are often provided in the case of detecting approach of an object. However, in the case where the input/output port of the general-purpose microcomputer as illustrated in FIG. 5 is used, there is a fear that the voltage of the integration capacitor Ci 46 may largely change due to leakage current or the like during intervals, and hence initialization is often required.

In a case where the voltage of the integration capacitor Ci 46 deviates slightly from the steady state, it is possible to perform only the run-up without performing the threshold approach and the centering.

The case where equilibrium voltage is made higher due to capacitance change has been described above, but the above-mentioned operation is applied to the reverse case.

Further, also in the second embodiment, as in the case of the first embodiment, it becomes possible to determine an electrostatic capacitance Cx of the detection target 40 with such a simpler configuration as to merely add the integration resistor Ri 48 and the integration capacitor Ci 46 to one input/output port of the general-purpose microcomputer as illustrated in FIG. 5. Note that the integration resistor Ri 48 and the integration capacitor Ci 46 are connected in series, and it is needless to say that places of the integration resistor Ri 48 and the integration capacitor Ci 46 may be exchanged. In this case, the sampling means 24 of the sampling step 63, the arithmetic means 25 of the arithmetic step 64, and the CV control means 27 of the CV control step 66 are realized by the CPU 51 included in the microcomputer 52.

Further, also in the second embodiment, as in the case of the first embodiment, by connecting electrostatic capacitances of a plurality of detection electrodes which are arranged on the support substrate 70 in a one-dimensional direction with a plurality of ports of the same microcomputer, as illustrated in FIG. 12A, it becomes possible to constitute a slider which detects approach of an object and a position thereof in the one-dimensional direction based on values respectively corresponding to the electrostatic capacitances of the detection electrodes.

Further, as illustrated in FIG. 12B, by arranging detection electrodes corresponding to two-dimensional coordinates on the support substrate 70, it becomes possible to constitute an electrostatic capacitance detection device which detects approach of an object and a position thereof in a two-dimensional direction in a similar manner to the above.

As described above, according to the second embodiment of the present invention, it becomes possible to realize the electrostatic capacitance detection circuit and the electrostatic capacitance detection method which are capable of detecting change in electrostatic capacitance of the detection target 40 at high speed and high resolution with a simpler configuration with low component cost.

Further, according to this embodiment, the detection range can be controlled by setting the timings at which the switches are turned on/off, which makes it possible to perform programmable range setting.

What is claimed is:

1. An electrostatic capacitance detection device which detects an approach position of an object by means of an electrostatic capacitance, the electrostatic capacitance detection device comprising:
a plurality of detection electrodes arranged on a support substrate;
CV conversion means, which is connected to each of the plurality of detection electrodes, for converting each of electrostatic capacitances of detection targets including the plurality of detection electrodes into a voltage waveform corresponding to the each of electrostatic capacitances, the CV conversion means each being formed of a resistor and a capacitor which are connected in series; and
a general-purpose microcomputer including input/output ports respectively connected to the plurality of detection electrodes,
the general-purpose microcomputer causing a CPU included in the general-purpose microcomputer to perform arithmetic operations on the approach position of the object based on values corresponding to one of the electrostatic capacitances of the plurality of detection electrodes and change in electrostatic capacitance.

2. An electrostatic capacitance detection device according to claim 1, wherein the general-purpose microcomputer of the electrostatic capacitance detection device is realized by comprising:
comparison means for comparing an output of the CV conversion means with a threshold voltage;
sampling means for sampling an output of the comparison means;
arithmetic means for determining the values corresponding to the one of the electrostatic capacitances of the detection targets and the change in electrostatic capacitance based on an output of the sampling means; and
CV control means for controlling switches of the input/output ports based on results of the arithmetic operations.

3. An electrostatic capacitance detection circuit which detects an approach position of an object by means of an electrostatic capacitance, the electrostatic capacitance detection circuit comprising:
CQ supplement means for converting an electrostatic capacitance of a detection target into a charge quantity corresponding to the electrostatic capacitance of the detection target, and supplementing with a charge quantity corresponding to the converted charge quantity and performing integration;
comparison means for comparing an output of the CQ supplement means with a threshold voltage;
sampling means for sampling an output of the comparison means, and providing negative feedback to the CQ supplement means; and
arithmetic means for determining a value corresponding to the electrostatic capacitance of the detection target based on an output of the sampling means,
the CQ supplement means comprising:
a first constant voltage source;
a second constant voltage source;
a first switch;
a first resistor;
a second resistor; and
a capacitor,
the first switch having one terminal connected to the first constant voltage source, and another terminal connected to the electrostatic capacitance of the detection target and to one terminal of the first resistor,
the first resistor having another terminal connected to one terminal of the second resistor,
the second resistor having another terminal connected to the second constant voltage source,
the capacitor having one terminal connected to a connection terminal between the first resistor and the second resistor.

4. An electrostatic capacitance detection circuit which detects an approach position of an object by means of an electrostatic capacitance, the electrostatic capacitance detection circuit comprising:
CQ supplement means for converting an electrostatic capacitance of a detection target into a charge quantity corresponding to the electrostatic capacitance of the detection target, and supplementing with a charge quantity corresponding to the converted charge quantity and performing integration;
comparison means for comparing an output of the CQ supplement means with a threshold voltage;
sampling means for sampling an output of the comparison means, and providing negative feedback to the CQ supplement means; and
arithmetic means for determining a value corresponding to the electrostatic capacitance of the detection target based on an output of the sampling means,
the CQ supplement means comprising:
a first constant voltage source;
a second constant voltage source;
a first switch;
a second switch;
a third resistor; and
a capacitor,
the first switch having one terminal connected to the first constant voltage source,
the first switch having another terminal connected to the electrostatic capacitance of the detection target, to one terminal of the second switch, and to one terminal of one of the third resistor and the capacitor which are connected in series,
the second switch having another terminal connected to the second constant voltage source.

5. An electrostatic capacitance detection circuit which detects an approach position of an object by means of an electrostatic capacitance, the electrostatic capacitance detection circuit comprising:
CV conversion means for converting an electrostatic capacitance of a detection target into a voltage waveform corresponding to the electrostatic capacitance of the detection target;
comparison means for comparing an output of the CV conversion means with a threshold voltage;
sampling means for sampling an output of the comparison means; and
arithmetic means for determining a value corresponding to the electrostatic capacitance of the detection target based on an output of the sampling means.

6. An electrostatic capacitance detection circuit according to claim 5, wherein the CV conversion means comprises:
a first constant voltage source;
a second constant voltage source;
a first switch;
a first resistor;
a second resistor; and
a capacitor,
the first switch having one terminal connected to the first constant voltage source, and another terminal connected to the electrostatic capacitance of the detection target and to one terminal of the first resistor,
the first resistor having another terminal connected to one terminal of the second resistor,
the second resistor having another terminal connected to the second constant voltage source,
the capacitor having one terminal connected to a connection terminal between the first resistor and the second resistor.

7. An electrostatic capacitance detection circuit according to claim 5, wherein the CV conversion means comprises:
a first constant voltage source;
a second constant voltage source;
a first switch;
a second switch;
a third resistor; and
a capacitor,
the first switch having one terminal connected to the first constant voltage source,
the first switch having another terminal connected to the electrostatic capacitance of the detection target, to one terminal of the second switch, and to one terminal of one of the third resistor and the capacitor which are connected in series,
the second switch having another terminal connected to the second constant voltage source.

8. An electrostatic capacitance detection device according to claim 2, wherein a ratio of a single turn-on period of the first switch to a single turn-on period of the second switch is one of 1:0.7 or less and 1:1.5 or more.

9. An electrostatic capacitance detection device according to claim 4, wherein a ratio of a single turn-on period of the first switch to a single turn-on period of the second switch is one of 1:0.7 or less and 1:1.5 or more.

10. An electrostatic capacitance detection device according to claim 7, wherein a ratio of a single turn-on period of the first switch to a single turn-on period of the second switch is one of 1:0.7 or less and 1:1.5 or more.

11. An electrostatic capacitance detection method of detecting one of an electrostatic capacitance and change in electrostatic capacitance, the electrostatic capacitance detection method comprising:
a CV conversion step of converting an electrostatic capacitance of a detection target into a voltage waveform corresponding to the electrostatic capacitance of the detection target;
a comparison step of comparing an output obtained in the CV conversion step with a threshold voltage;
a CV control step of controlling the output of the CV conversion step so that a DC component of the voltage waveform output in the CV conversion step changes in correspondence with the electrostatic capacitance of the detection target and that the threshold voltage of the comparison step falls within a variation range of an AC component of the voltage waveform;
a sampling step of sampling an output of the comparison step; and
an arithmetic step of determining a value corresponding to the electrostatic capacitance of the detection target based on an output of the sampling step.

12. An electrostatic capacitance detection method according to claim 11, wherein the CV control step includes controlling the output of the CV conversion step based on arithmetic results of the arithmetic step.

13. An initialization method of shifting a capacitor from an initialization state before detection to a steady state, which is used in an electrostatic capacitance detection method of detecting one of an electrostatic capacitance and change in electrostatic capacitance, the initialization method comprising a threshold approach step of making a voltage of the capacitor approximate to a threshold voltage of a comparison step by controlling, when the voltage of the capacitor is higher than the threshold voltage of the comparison step, a switch to which a constant voltage source having a voltage lower than the threshold voltage of the comparison step is connected to be continuously turned on until an output of the comparison step is changed, and by controlling, when the voltage of the capacitor is lower than the threshold voltage of the comparison step, a switch to which a constant voltage source having a voltage higher than the threshold voltage is connected to be continuously turned on until an output of the comparison step is changed.

14. An initialization method of shifting a capacitor from an initialization state before detection to a steady state, which is used in an electrostatic capacitance detection method of detecting one of an electrostatic capacitance and change in electrostatic capacitance according to claim 13, the initialization method comprising, in addition to the threshold approach step, a centering step of adjusting the voltage of the capacitor substantially at a center of a detection range by controlling, when the voltage of the capacitor is higher than the threshold voltage of the comparison step, the switch to which the constant voltage source having the voltage lower than the threshold voltage of the comparison step is connected to be continuously turned on/off for a number of times which is smaller than a number of times the switch is continuously turned on/off during a CQ conversion step, and by controlling, when the voltage of the capacitor is lower than the threshold voltage of the comparison step, the switch to which the constant voltage source having the voltage, higher than the threshold voltage is connected to be continuously turned on/off for a number of times which is smaller than a number of times the switch is continuously turned on/off during the CQ conversion step.

15. An initialization method of shifting a capacitor from an initialization state before detection to a steady state, which is used in an electrostatic capacitance detection method of detecting one of an electrostatic capacitance and change in electrostatic capacitance, the initialization method comprising a run-up step of repeating, at least once, operations of controlling a first switch to be continuously turned on/off for a number of times which is equal to a number of times the first switch is continuously turned on/off during a CQ conversion step, and of controlling a second switch to be continuously turned on/off for a number of times which is equal to a number of times the second switch is continuously turned on/off during the CQ conversion step.
